(19) United States
(12) Patent Application Publication
(10) Pub. No.: US 2018/0286302 A1
(43) Pub. Date: Oct. 4, 2018

(54) SHIFT REGISTERS, DRIVING METHODS THEREOF, AND GATE DRIVING CIRCUITS

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventor: Silin Feng, Beijing (CN)

(21) Appl. No.: 15/793,904

(22) Filed: Oct. 25, 2017

(30) Foreign Application Priority Data
Mar. 28, 2017 (CN) 201710192071.X

(51) Int. Cl. G09G 3/20; G11C 19/28

(52) U.S. Cl. CPC G09G 3/2092; G11C 19/287; G09G 2310/0243; G09G 2310/0289; G09G 2310/0286

(57) ABSTRACT

The embodiments of the present disclosure disclose a shift register, a method for driving the same, and a gate driving circuit. The shift register may include an inputting circuit, configured to apply a signal at a first signal terminal to a pulling up node; a resetting circuit, configured to apply a signal at a second signal terminal to the pulling up node; an outputting circuit, configured to apply a signal at a first clock terminal to an outputting terminal; a pulling down circuit, configured to apply a signal at a constant level terminal to the pulling up node and the outputting terminal according to the potential at a pulling down node, and to apply a signal at the constant level terminal to the pulling up node and the outputting terminal; a pull-down controlling circuit, configured to control the potential at the pulling down node; and a storage capacitor.

### TECHNICAL FIELD

The present disclosure relates to the field of gate driving circuits, and more particularly, to a shift register, a driving method thereof, and a gate driving circuit.

### BACKGROUND

To simplify the structure of display panels, a gate driving circuit (GOA) formed on an array substrate can be used to drive gate lines. The gate driving circuit may comprise a plurality of cascaded shift register units.

In displaying a frame, the scanning of the gate lines will be completed in a short time. The remaining time is referred to as Blank time. Especially, in a case that bi-directional scanning is performed, when beginning to scan a next frame (i.e. respective shift register unit restarts for scanning), each of the shift register units, especially a last stage of shift register unit, will be in an abnormal state, affecting the display quality.

### SUMMARY

According to an aspect of the present disclosure, a shift register unit is provided, which may comprise:

an inputting circuit, connected with an inputting terminal, a first signal terminal and a pulling up node, and configured to apply a signal at the first signal terminal to the pulling up node, under the control of a potential at the inputting terminal,

a resetting circuit, connected with a resetting terminal, a second signal terminal and the pulling up node, and configured to apply a signal at the second signal terminal to the pulling up node, under the control of a potential at the resetting terminal;

an outputting circuit, connected with an outputting terminal, a first clock terminal and the pulling up node, and configured to apply a signal at the first clock terminal to the outputting terminal according to a potential at the pulling up node

a pulling down circuit, connected with a third signal terminal, a second clock terminal, a constant level terminal, the outputting terminal, the pulling up node and a pulling down node, and configured to apply a signal at the constant level terminal to the pulling up node and the outputting terminal according to the potential at the pulling down node, and to apply a signal at the constant level terminal to the pulling up node and the outputting terminal under the control of a potential at the third signal terminal;

a pull-down controlling circuit, connected with the second clock terminal, the pulling up node, the pulling down node and the constant level terminal, and configured to control the potential at the pulling down node according to the signal at the second clock terminal and the potential of the pulling up node; and

a storage capacitor, having a first terminal connected with the pulling up node and a second terminal connected with the pulling down node.

According to the embodiments of the present disclosure, the inputting circuit may comprise a first transistor having a gate connected with the inputting terminal, a first terminal connected with the first signal terminal and a second terminal being connected with the pulling up node.

According to the embodiments of the present disclosure, the resetting circuit may comprise a second transistor having a gate being connected with the resetting terminal, a first terminal being connected with the pulling up node and a second terminal being connected with the second signal terminal.

According to the embodiments of the present disclosure, the outputting circuit comprises a third transistor having a gate connected with the pulling up node, a first terminal connected with the first clock terminal and a second terminal connected with the outputting terminal.

According to the embodiments of the present disclosure, the pulling down circuit may comprise a fourth transistor, a fifth transistor, a sixth transistor, a seventh transistor, an eighth transistor and a ninth transistor, wherein: the fourth transistor has a gate connected with the second clock terminal, a first terminal connected with the outputting terminal and a second terminal connected with the constant level terminal; the fifth transistor has a gate connected with the pulling down node, a first terminal connected with the pulling up node and a second terminal connected with the constant level terminal; the sixth transistor has a gate connected with the pulling down node, a first terminal connected with the outputting terminal and a second terminal connected with the constant level terminal; the seventh transistor has a gate connected with the third signal terminal, a first terminal connected with the pulling up node and a second terminal connected with the constant level terminal; the eighth transistor has a gate connected with the third signal terminal, a first terminal connected with the pulling down node and a second terminal connected with the third signal terminal; and the ninth transistor has a gate connected with the third signal terminal, a first terminal connected with the outputting terminal and a second terminal connected with the constant level terminal.

According to the embodiments of the present disclosure, the pull-down controlling circuit may comprise a tenth transistor, an eleventh transistor, a twelfth transistor and a thirteenth transistor, wherein: the tenth transistor has a gate connected with a second terminal of the thirteenth transistor, a first terminal connected with the second clock terminal and a second terminal connected with the pulling down node; the eleventh transistor has a gate connected with the pulling up node, a first terminal connected with the pulling down node and a second terminal connected with the constant level terminal; the twelfth transistor has a gate connected with a pulling up node, a first terminal connected with the second terminal of the thirteenth transistor and a second terminal connected with the constant level terminal; and the thirteenth transistor has a gate connected with the second clock terminal and a first terminal connected with the second clock terminal.

According to the embodiments of the present disclosure, all of the transistors may be N-type transistors.

According to the embodiments of the present disclosure, all of the transistors may be P-type transistors.

According to another aspect of the present disclosure, there is provided a gate driving circuit comprising a plurality of cascaded shifter register units as discussed above.

According to another aspect of the present disclosure, there is provided a method for driving the shift register unit of above embodiments, comprising:

providing a turning off signal to the constant level terminal and a turning on signal to the third signal terminal, at a Blank time, so as to apply the turning off signal at the constant level terminal to the pulling up node and the outputting terminal.

According to the embodiments of the present disclosure, the transistors are N-type transistors, and a high potential is provided to the first signal terminal, a low potential is provided to the second signal terminal, and a low potential is provided to the constant level terminal, the method further comprising:

inputting a high potential to the inputting terminal, a low potential to the first clock terminal, a high potential to the second clock terminal, a low potential to the resetting terminal, and a low potential to the third signal terminal, at a Charging time;

inputting a low potential to the inputting terminal, a high potential to the first clock terminal, a low potential to the second clock terminal, a low potential to the resetting terminal, and a low potential to the third signal terminal, at an Outputting time;

inputting a low potential to the inputting terminal, a low potential to the first clock terminal, a high potential to the second clock terminal, a high potential to the resetting terminal, and a low potential to the third signal terminal, at a Resetting time;

inputting a low potential to the inputting terminal, a high potential to the first clock terminal and the second clock terminal alternatively, a low potential to the resetting terminal, a low potential to the third signal terminal, at a Holding time; and

inputting a low potential to the inputting terminal, a low potential to the first clock terminal, a low potential to the second clock terminal, a low potential to the resetting terminal, and a high potential to the third signal terminal, at the Blank time.

According to the embodiments of the present disclosure, the transistors are N-type transistors, and a low potential is provided to the first signal terminal, a high potential is provided to the second signal terminal, and a low potential is provided to the constant level terminal, the method further comprising:

inputting a high potential to the resetting terminal, a low potential to the first clock terminal, a high potential to the second clock terminal, a low potential to the inputting terminal, and a low potential to the third signal terminal, at a Charging time;

inputting a low potential to the resetting terminal, a high potential to the first clock terminal, a low potential to the second clock terminal, a low potential to the inputting terminal, and a low potential to the third signal terminal, at an Outputting time;

inputting a low potential to the resetting terminal, a low potential to the first clock terminal, a high potential to the second clock terminal, a high potential to the inputting terminal, and a low potential to the third signal terminal, at a Resetting time;

inputting a low potential to the resetting terminal, a high potential to the first clock terminal and the second clock terminal alternatively, a low potential to the inputting terminal, a low potential to the third signal terminal, at a Holding time; and

inputting a low potential to the resetting terminal, a low potential to the first clock terminal, a low potential to the second clock terminal, a low potential to the inputting terminal, and a high potential to the third signal terminal, at the Blank time.

According to the embodiments of the present disclosure, the transistors are P-type transistors, and a low potential is provided to the first signal terminal, a high potential is provided to the second signal terminal, and a high potential is provided to the constant level terminal, the method further comprising:

inputting a low potential to the inputting terminal, a high potential to the first clock terminal, a low potential to the second clock terminal, a high potential to the resetting terminal, and a high potential to the third signal terminal, at a Charging time;

inputting a high potential to the inputting terminal, a low potential to the first clock terminal, a high potential to the second clock terminal, a high potential to the resetting terminal, and a high potential to the third signal terminal, at an Outputting time;

inputting a high potential to the inputting terminal, a high potential to the first clock terminal, a low potential to the second clock terminal, a low potential to the resetting terminal, and a high potential to the third signal terminal, at a Resetting time;

inputting a high potential to the inputting terminal, a low potential to the first clock terminal and the second clock terminal alternatively, a high potential to the resetting terminal, and a high potential to the third signal terminal, at a Holding time; and

inputting a high potential to the inputting terminal, a high potential to the first clock terminal, a high potential to the second clock terminal, a high potential to the resetting terminal, and a low potential to the third signal terminal, at the Blank time.

According to the embodiments of the present disclosure, the transistors are P-type transistors, and a high potential is provided to the first signal terminal, a low potential is provided to the second signal terminal, and a high potential is provided to the constant level terminal, the method further comprising:

inputting a low potential to the resetting terminal, a high potential to the first clock terminal, a low potential to the second clock terminal, a high potential to the inputting terminal, and a high potential to the third signal terminal, at a Charging time;

inputting a high potential to the resetting terminal, a low potential to the first clock terminal, a high potential to the second clock terminal, a high potential to the inputting terminal, and a high potential to the third signal terminal, at an Outputting time;

inputting a high potential to the resetting terminal, a high potential to the first clock terminal, a low potential to the second clock terminal, a low potential to the inputting terminal, and a high potential to the third signal terminal, at a Resetting time;

inputting a high potential to the resetting terminal, a low potential to the first clock terminal and the second clock terminal alternatively, a high potential to the inputting terminal, and a high potential to the third signal terminal, at a Holding time; and

inputting a high potential to the resetting terminal, a high potential to the first clock terminal, a high potential to the second clock terminal, a high potential to the inputting terminal, and a low potential to the third signal terminal, at the Blank time.

### BRIEF DESCRIPTION OF THE DRAWINGS

FIG. 1 is a circuit diagram illustrating a shift register unit according to an embodiment of the present disclosure;

FIG. 2 is a schematic block diagram illustrating a gate driving circuit according to an embodiment of the present disclosure;

FIG. 3 is a timing diagram of a shift register unit which scans forward according to an embodiment of the present disclosure;

FIG. 4 is a timing diagram of a shift register unit which scans in reverse according to an embodiment of the present disclosure; and

FIG. 5 is a circuit diagram illustrating a conventional shift register unit.

### DETAILED DESCRIPTION

In order to make a better understanding of the inventive concept of the present disclosure, the present disclosure now be described in further detail with reference to the accompanying drawings and specific embodiments.

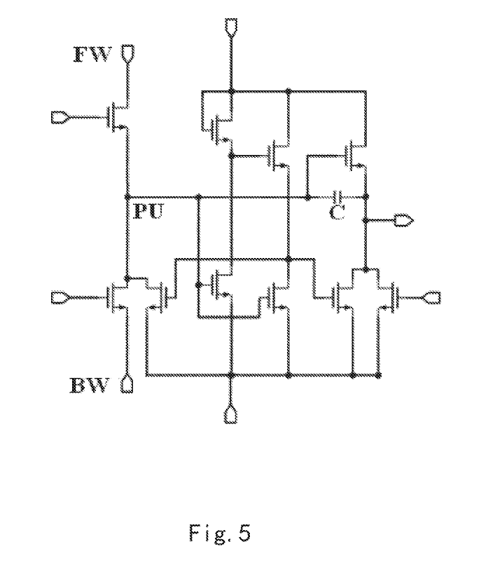

As shown in FIG. 5, in order to realize a bidirectional scanning, it is necessary to provide a first signal terminal FW and a second signal terminal BW, wherein one of them has a high potential and the other has a low potential. The scanning direction varies with the terminal having the high potential. In displaying a frame, the scanning of the lines will be completed in a short time. The remaining time is referred to as Blank time. At the Blank time, signals at terminals other than the first signal terminal FW and the second signal terminal BW are kept at a low potential. When a display panel scans bi-directionally, due to the facts that one of the first signal terminal FW and the second signal terminal BW remains at a high potential at the Blank time and a transistor inevitably has a leakage current, a storage capacitor C will be charged gradually at this time, causing the potential at a pulling up node PU of a shift register unit being increased gradually. Thus, the transistor for controlling an output will be in an unsaturated state, which enables respective shift register units to restart when displaying the next frame. Shift register units, especially the last stage of shift register unit, will be in an abnormal state, affecting the display quality.

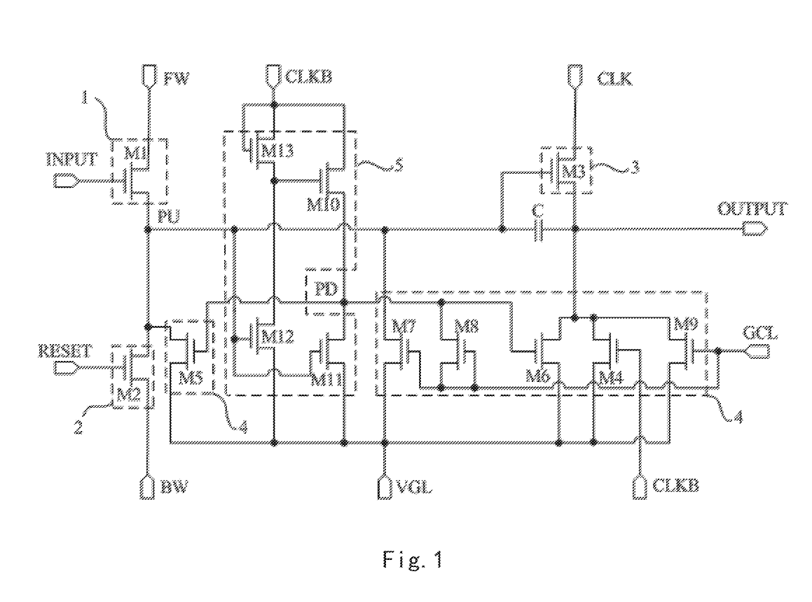

As shown in FIGS. 1 to 4, the present embodiment provides a shift register unit comprising following components. An inputting circuit 1 is connected with an inputting terminal INPUT, a first signal terminal FW and a pulling up node PU, and is configured to apply a signal at the first signal terminal FW to the pulling up node PU, under the control of a potential at the inputting terminal INPUT.

A resetting circuit 2 may be connected with a resetting terminal RESET, a second signal terminal BW and the pulling up node PU, and configured to apply a signal at the second signal terminal BW to the pulling up node PU, under the control of a potential at the resetting terminal RESET.

An outputting circuit 3 may be connected with an outputting terminal OUTPUT, a first clock terminal CLK and the pulling up node PU, and configured to apply a signal at the first clock terminal CLK to the outputting terminal OUTPUT according to a potential at the pulling up node PU.

A pulling down circuit 4 may be connected with a third signal terminal GCL, a second clock terminal CLKB, a constant level terminal VGL, the outputting terminal OUTPUT, the pulling up node PU and a pulling down node PD, and configured to apply a signal at the constant level terminal VGL to the pulling up node PU and the outputting terminal OUTPUT according to the potential at the pulling down node PD, and to apply a signal at the constant level terminal VGL to the pulling up node PU and the outputting terminal OUTPUT under the control of a potential at the third signal terminal GCL.

A pull-down controlling circuit 5 may be connected with the second clock terminal CLKB, the pulling up node PU, the pulling down node PD and the constant level terminal VGL, and configured to control the potential at the pulling down node PD according to the signal at the second clock terminal CLKB and the potential of the pulling up node PU.

A storage capacitor may have a first terminal connected with the pulling up node PU and a second terminal connected with the pulling down node PD.

As an example, the inputting circuit 1 may comprise a first transistor M1 having a gate connected with the inputting terminal INPUT, a first terminal connected with the first signal terminal FW and a second terminal being connected with the pulling up node PU.

For another example, the resetting circuit 2 may comprise a second transistor M2 having a gate being connected with the resetting terminal RESET, a first terminal being connected with the pulling up node PU and a second terminal being connected with the second signal terminal BW.

For another example, the outputting circuit 3 may comprise a third transistor M3 having a gate connected with the pulling up node PU, a first terminal connected with the first clock terminal CLK and a second terminal connected with the outputting terminal OUTPUT.

For another example, the pulling down circuit 4 may comprise a fourth transistor M4, a fifth transistor M5, a sixth transistor M6, a seventh transistor M7, an eighth transistor M8 and a ninth transistor M9. The fourth transistor M4 has a gate connected with the second clock terminal CLKB, a first terminal connected with the outputting terminal OUTPUT and a second terminal connected with the constant level terminal VGL. The fifth transistor M5 has a gate connected with the pulling down node PD, a first terminal connected with the pulling up node PU and a second terminal connected with the constant level terminal VGL. The sixth transistor M6 has a gate connected with the pulling down node PD, a first terminal connected with the outputting terminal OUTPUT and a second terminal connected with the constant level terminal VGL. The seventh transistor M7 has a gate connected with the third signal terminal GCL, a first terminal connected with the pulling up node PU and a second terminal connected with the constant level terminal VGL. The eighth transistor M8 has a gate connected with the third signal terminal GCL, a first terminal connected with the pulling down node PD and a second terminal connected with the third signal terminal GCL. The ninth transistor M9 has a gate connected with the third signal terminal GCL, a first terminal connected with the outputting terminal OUTPUT and a second terminal connected with the constant level terminal VGL.

For another example, the pull-down controlling circuit may comprise a tenth transistor M10, an eleventh transistor M11, a twelfth transistor M12 and a thirteenth transistor M13. The tenth transistor M10 has a gate connected with a second terminal of the thirteenth transistor M13, a first terminal connected with the second clock terminal CLKB and a second terminal connected with the pulling down node PD. The eleventh transistor M11 has a gate connected with the pulling up node PU, a first terminal connected with the pulling down node PD and a second terminal connected with the constant level terminal VGL. The twelfth transistor M12 has a gate connected with a pulling up node PU, a first terminal connected with the second terminal of the thirteenth transistor M13 and a second terminal connected with the constant level terminal VGL. The thirteenth transistor M13 has a gate connected with the second clock terminal CLKB and a first terminal connected with the second clock terminal CLKB.

For an example, all of the transistors are N-type transistors. For another example, all of the transistors are P-type transistors.

In other words, all of the transistors in the shift register unit (i.e. the first transistor M1 to the thirteenth transistor M13) may be the same type of transistors.

The embodiments of the disclosure may further provide a gate driving circuit, comprising a plurality of cascaded shift register units as discussed above.

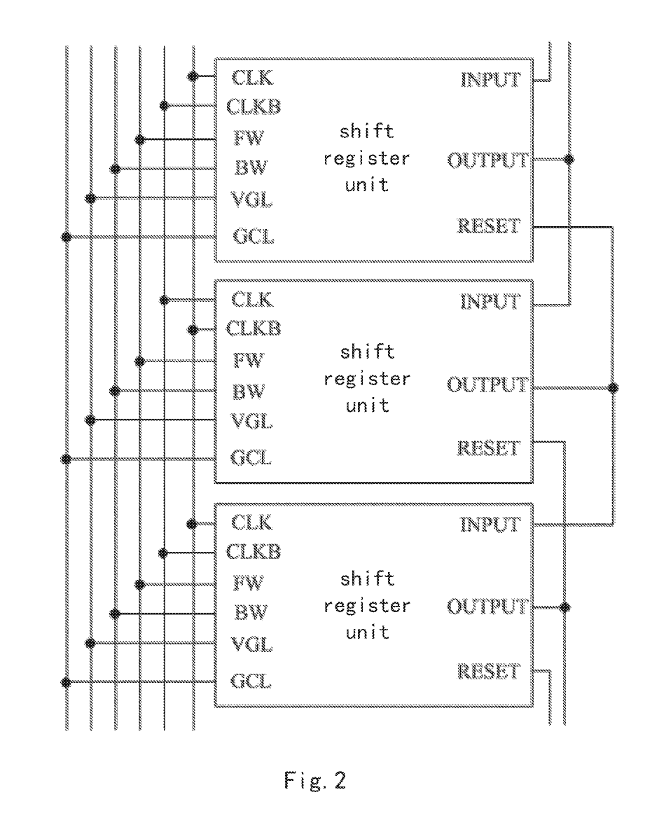

As shown in FIG. 2, a plurality of shift register units as discussed above may be cascaded, constituting a gate driving circuit. The outputting terminal OUTPUT of each shift register unit is connected with a line, so as to drive the corresponding line.

In particular, each of various stages of shift register except for a last stage of shift register has an outputting terminal OUTPUT connected with an inputting terminal INPUT of a next stage of shift register. Certainly, the inputting terminal INPUT of the first stage of shift register is connected with a separate driving signal. Further, each of various stages of shift register except for a first stage of shift register has an outputting terminal OUTPUT further connected with a resetting terminal RESET of a previous stage of shift register. Certainly, the resetting terminal RESET of the last stage of shift register is connected with a separate driving signal.

For any two adjacent shift registers, their clock terminals are connected with the opposite clock signal lines. If one stage of shift register has its first clock terminal CLK connected with the first clock signal line and its second clock terminal CLKB connected with the second clock signal line, the other stage of shift register has a first clock terminal CLK connected with the second clock signal line, and a second clock terminal CLKB connected with the first clock signal line.

The embodiments of the present disclosure also provides a method for driving the shift register unit as discussed above. The method may comprise providing a turning off signal to the constant level terminal VGL and a turning on signal to the third signal terminal GCL at a Blank time, so as to apply the turning off signal at the constant level terminal VGL to the pulling up node PU and the outputting terminal OUTPUT.

At the Blank time, the shift register of the present embodiment may provide a turning on signal by the third signal terminal GCL, and apply the turn-off signal at the constant level terminal to the pulling up node PU and the outputting terminal OUTPUT, so as to enable the shift register to output a low potential constantly and stably, to prevent the potential at the pulling up node PU from being raised to its leakage, and eliminate the charge accumulation at the storage capacitor C, thereby avoiding being abnormal at the beginning of the next frame.

It should be noted that the operation of the shifter register unit of the present disclosure are described by taking all transistors in the shift register unit being N-type transistors as an example. Since the shift register is capable of scanning bi-directionally, the procedure of forward and reverse scanning is described separately.

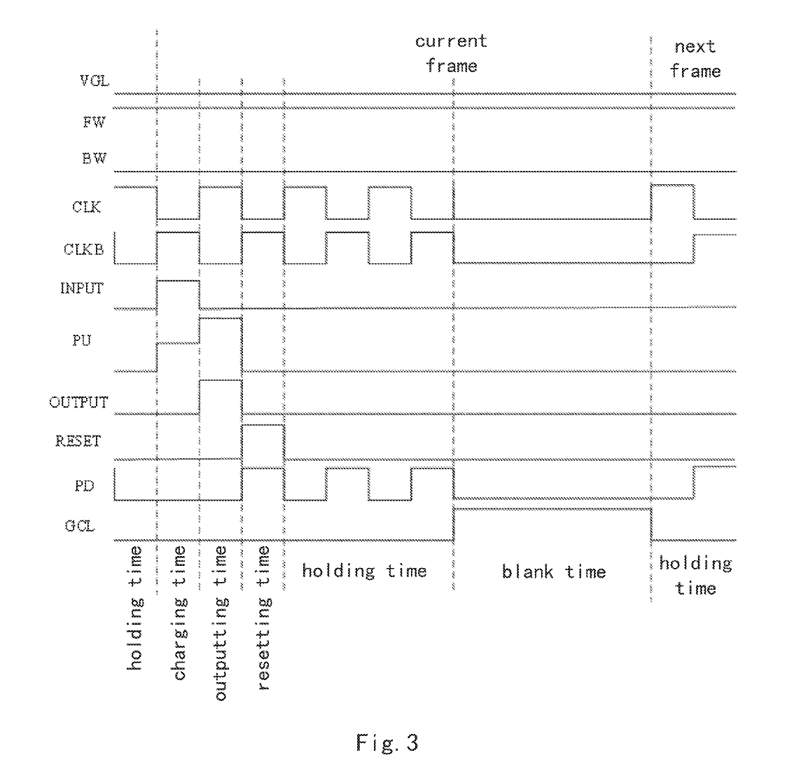

As shown in FIG. 3, when a forward scanning (i.e., scanning from a low stage of shift register to a high stage of shift register) is performed, a high potential is provided to the first signal terminal FW, a low potential is provided to the second signal terminal BW, and a low potential is provided to the constant level terminal VGL. The process of driving the shift register may include: inputting a high potential to the inputting terminal INPUT, a low potential to the first clock terminal CLK, a high potential to the second clock terminal CLKB, a low potential to the resetting terminal RESET, and a low potential to the third signal terminal GCL, at a Charging time of S11.

At this time, the inputting terminal INPUT is a high potential signal output from the previous stage of shift register. Thus, the first transistor M1 can be turned on, and the high potential at the first signal terminal FW can be applied into the pulling up node PU. The third transistor M3 is turned on, and the low potential at the first clock terminal CLK is applied to the outputting terminal OUTPUT. Therefore, the shift register outputs at a low potential, and the storage capacitor C will be charged. Since the pulling up node PU is high, the eleventh transistor M11 and the twelfth transistor M12 are turned on. The thirteenth transistor M13 and the tenth transistor M10 are turned off. Although the second clock terminal CLKB is at a high potential, the pulling down node PD is at a low potential.

At an Outputting time of S12, a low potential is provided to the inputting terminal INPUT, a high potential is provided to the first clock terminal CLK, a low potential is provided to the second clock terminal CLKB, a low potential is provided to the resetting terminal RESET, and a low potential is provided to the third signal terminal GCL.

At this time, the inputting terminal INPUT goes low, so the first transistor M1 is turned off. Consequently, the pulling up node PU cannot be discharged and thus remains at a high potential. The third transistor M3 remains turned on. The high potential at the first clock terminal CLK is provided to the outputting terminal OUTPUT, so that the shift register outputs at a high potential. Due to the bootstrap function of the storage capacitor C, the potential at the pulling up node PU will be further raised, but it is still a high potential.

At a Resetting time of S13, a low potential is provided to the inputting terminal INPUT, a low potential is provided to the first clock terminal CLK, a high potential is provided to the second clock terminal CLKB, a high potential is provided to the resetting terminal RESET, and a low potential is provided to the third signal terminal GCL.

At this time, the reset terminal RESET is a high potential signal output from the next stage of shift register, and thus the second transistor M2 is turned on. The low potential at the second signal terminal BW is applied to the pulling up node PU, and the pulling up node PU becomes low. The second clock terminal CLKB is also at a high potential, so the fourth transistor M4 is turned on, and the low potential at the constant level terminal VGL is applied to the outputting terminal OUTPUT. The shift register outputs at a low potential, and the storage capacitor C discharges. Since the pulling up node PU is at a low potential and the eleventh transistor M11 and the twelfth transistor M12 are turned off, the high potential at the second clock terminal CLKB may cause the tenth transistor M10 and the thirteenth transistor M13 to be turned on. The high potential at the second clock terminal CLKB is applied to the pulling down node PD via the thirteenth transistor M13. The pulling down node PD is at a high potential and the low potential at the constant level terminal VGL is applied to the pulling up node PU and the outputting terminal OUTPUT via the fifth transistor M5 and the sixth transistor M6, respectively, so as to ensure that the storage capacitor C is completely discharged.

At a Holding time of S14, a low potential is provided to the inputting terminal INPUT, a high potential is provided to the first clock terminal CLK and the second clock terminal CLKB alternatively, a low potential is provided to the resetting terminal RESET, and a low potential is provided to the third signal terminal GCL.

At this time, this stage of shift register has already completed the procedure of scanning or is waiting for scanning, while the other stage of shift registers are scanning. The first clock terminal CLK and the second clock terminal CLKB are alternately high. When the second clock terminal CLKB is at a high potential, the pulling down node PD is at a high potential, and the low potential at the constant level terminal VGL is applied to the outputting terminal OUTPUT and the pulling up node PU. Since the time interval of the second clock terminal CLKB being at a high potential is very short, the outputting terminal OUTPUT can remain at a low potential.

At the Blank time of S15, a low potential is provided to the inputting terminal INPUT, a low potential is provided to the first clock terminal CLK, a low potential is provided to the second clock terminal CLKB, a low potential is provided to the resetting terminal RESET, and a high potential is provided to the third signal terminal GCL.

At this time, all of the shift registers has completed scanning, or the inputting of current frame has been completed. Thus, the shift register does not work any longer, and the display panel keeps in displaying the current frame. The various stages of shift registers will restart scanning at the beginning of the next frame. For example, the third signal terminal GCL is kept at a high potential, so that the ninth transistor M9 and the seventh transistor M7 are both turned on. The low potential at the constant level terminal VGL is continuously applied to the pulling up node PU and the inputting terminal INPUT. As a result, the shift register can output at a low potential continuously and stably, the potential at the pulling up node PU can be prevented from being raised by leakage, and the charge accumulation of the storage capacitor C can be eliminated. Therefore, at the beginning of the next frame, an abnormal output can be avoided especially for the last stage of shift register. Due to which, the display quality can be ensured.

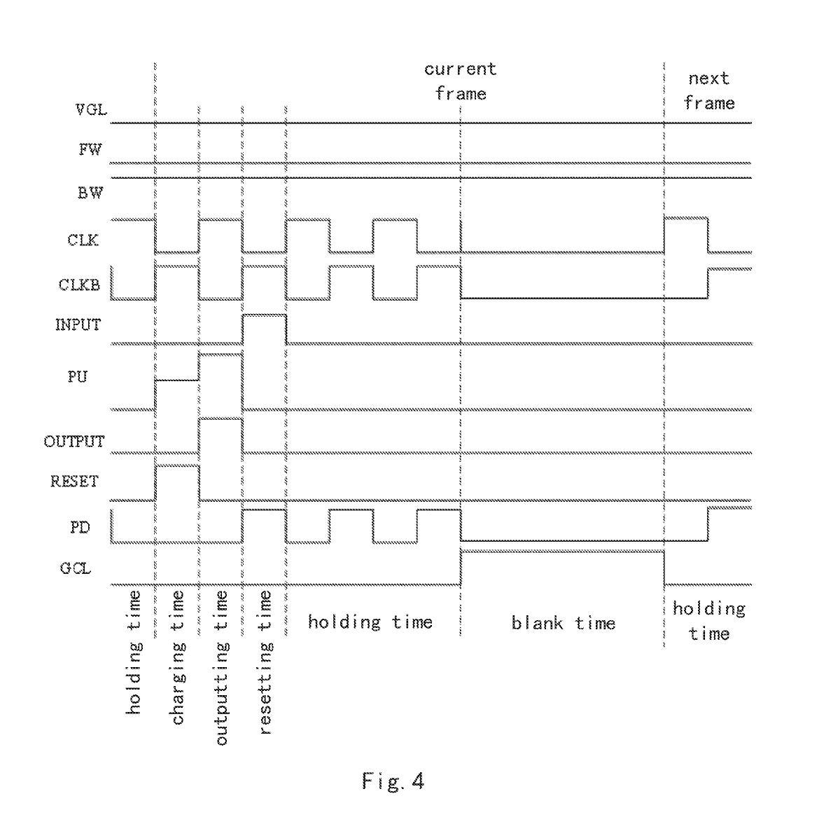

As shown in FIG. 4, when a reverse scanning (i.e., scanning from a high stage of shift register to a low stage of shift register) is performed, a low potential is provided to the first signal terminal FW, a high potential is provided to the second signal terminal BW, and a low potential is provided to the constant level terminal VGL. The process of driving the shift register may include following steps.

At a Charging time of S21, a high potential is provided to the resetting terminal RESET, a low potential is provided to the first clock terminal CLK, a high potential is provided to the second clock terminal CLKB, a low potential is provided to the inputting terminal INPUT, and a low potential is provided to the third signal terminal GCL.

At this time, the resetting terminal RESET is a high potential signal output from the next stage of shift register. Since the procedure of a reverse scanning is performed, the next stage of shift register first may output a turning on signal. The second transistor M2 is turned on, and the high potential at the second signal terminal BW is applied to the pulling up node PU. Thus, the third transistor M3 is turned on, and the low potential at the first clock terminal CLK is applied to the outputting terminal OUTPUT. Therefore, the shift register outputs at a low potential, enabling the storage capacitor C to be charged.

At an Outputting time of S22, a low potential is provided to the resetting terminal RESET, a high potential is provided to the first clock terminal CLK, a low potential is provided to the second clock terminal CLKB, a low potential is provided to the inputting terminal INPUT, and a low potential is provided to the third signal terminal GCL.

At this time, the reset terminal RESET goes low, so that the second transistor M2 is turned off. Thus, the pulling up node PU cannot be discharged and remains at a high potential, the third transistor M3 remains being turned on. The high power at the first clock terminal CLK is applied to the outputting terminal OUTPUT, so that the shift register outputs a turning on signal at a high potential.

at a Resetting time of S23, a low potential is provided to the resetting terminal RESET, a low potential is provided to the first clock terminal CLK, a high potential is provided to the second clock terminal CLKB, a high potential is provided to the inputting terminal INPUT, and a low potential is provided to the third signal terminal GCL.

At this time, the inputting terminal INPUT is a high potential signal output from the previous stage of shift register, so that the first transistor M1 is turned on. The low potential at the first signal terminal FW is applied into the pulling up node PU, and the pulling up node PU becomes low. The second clock terminal CLKB is also at a high potential, so the fourth transistor M4 is turned on. The low potential at the constant level terminal VGL is applied to the outputting terminal OUTPUT. Therefore, the shift register outputs at a low potential, and the storage capacitor C is discharged.

At a Holding time of S24, a low potential is provided to the resetting terminal RESET, a high potential is provided to the first clock terminal CLK and the second clock terminal CLKB alternatively, a low potential is provided to the inputting terminal INPUT, a low potential is provided to the third signal terminal GCL.

At this time, the second clock CLKB is at a high potential, and thus the pulling down node PD is also at a high potential. The low potential at the constant level terminal VGL is applied to the outputting terminal OUTPUT and the pulling up node PU. Since the time interval of the second clock terminal CLKB being at a high potential is very short, the outputting terminal OUTPUT can remain at a low potential.

At the Blank time of S25, a low potential is provided to the resetting terminal RESET, a low potential is provided to the first clock terminal CLK, a low potential is provided to the second clock terminal CLKB, a low potential is provided to the inputting terminal INPUT, and a high potential is provided to the third signal terminal GCL.

At this time, the third signal terminal GCL is kept at a high potential, so that the ninth transistor M9 and the seventh transistor M7 are both turned on. The low potential at the constant level terminal VGL is applied to the pulling up node PU and the inputting terminal INPUT continuously. As a result, the shift register can output at a low potential continuously and stably, the potential at the pulling up node PU can be prevented from being raised by leakage, and the charge accumulation of the storage capacitor C can be eliminated. Therefore, at the beginning of the next frame, an abnormal output can be avoided. Due to which, the display quality can be ensured.

The above description describes a case where all of the transistors in the shift register unit are N-type transistor as an example. In a case where all of the transistors are P-type transistors, the method for driving the shift register unit may include the following steps.

When a forward scanning is performed, a low potential is provided to the first signal terminal FW, a high potential is provided to the second signal terminal BW, and a high potential is provided to the constant level terminal VGL. The process of driving the shift register may include steps as follows.

At a Charging time, a low potential is provided to the inputting terminal INPUT, a high potential is provided to the first clock terminal CLK, a low potential is provided to the second clock terminal CLKB, a high potential is provided to the resetting terminal RESET, and a high potential is provided to the third signal terminal GCL.

At an Outputting time, a high potential is provided to the inputting terminal INPUT, a low potential to the first clock terminal CLK, a high potential is provided to the second clock terminal CLKB, a high potential is provided to the resetting terminal RESET, and a high potential is provided to the third signal terminal GCL.

At a Resetting time, a high potential is provided to the inputting terminal INPUT, a high potential to the first clock terminal CLK, a low potential to the second clock terminal CLKB, a low potential to the resetting terminal RESET, and a high potential is provided to the third signal terminal GCL.

At a Holding time, a high potential is provided to the inputting terminal INPUT, a low potential is provided to the first clock terminal CLK and the second clock terminal CLKB alternatively, a high potential is provided to the resetting terminal RESET, and a high potential is provided to the third signal terminal GCL.

At the Blank time, a high potential is provided to the inputting terminal INPUT, a high potential is provided to the first clock terminal CLK, a high potential is provided to the second clock terminal CLKB, a high potential is provided to the resetting terminal RESET, and a low potential is provided to the third signal terminal GCL.

When a reverse scanning is performed, a high potential is provided to the first signal terminal FW, a low potential is provided to the second signal terminal BW, and a high potential is provided to the constant level terminal VGL. The process of driving the shift register may include steps as follows.

At a Charging time, a low potential is provided to the resetting terminal RESET, a high potential is provided to the first clock terminal CLK, a low potential is provided to the second clock terminal CLKB, a high potential is provided to the inputting terminal INPUT, and a high potential is provided to the third signal terminal GCL.

At an Outputting time, a high potential is provided to the resetting terminal RESET, a low potential is provided to the first clock terminal CLK, a high potential is provided to the second clock terminal CLKB, a high potential is provided to the inputting terminal INPUT, and a high potential is provided to the third signal terminal GCL.

At a Resetting time, a high potential is provided to the resetting terminal RESET, a high potential is provided to the first clock terminal CLK, a low potential is provided to the second clock terminal CLKB, a low potential is provided to the inputting terminal INPUT, and a high potential is provided to the third signal terminal GCL.

At a Holding time, a high potential is provided to the resetting terminal RESET, a low potential is provided to the first clock terminal CLK and the second clock terminal CLKB alternatively, a high potential is provided to the inputting terminal INPUT, and a high potential is provided to the third signal terminal GCL.

At the Blank time, a high potential is provided to the resetting terminal RESET, a high potential is provided to the first clock terminal CLK, a high potential is provided to the second clock terminal CLKB, a high potential is provided to the inputting terminal INPUT, and a low potential is provided to the third signal terminal GCL.

It will be understood by those skilled in the art that in the above method for driving shift register unit in which all of the transistors are P-type transistors, the potential of respective driving signal is opposite to that in a case that all of the transistors are N-type transistors. Therefore, at any time, the working states of the transistor are actually the same, the operations of the shift register unit are also the same, so it is no longer described in detail.

It will be apparent to those skilled in the art that various modifications and variations can be made in the embodiments of the disclosure without departing from the spirit and scope of the embodiments of the disclosure. In this way, the present disclosure is intended to embrace such modifications and variations if these modifications and variations of the embodiments of the disclosure are within the scope of the appended claims and their equivalents.

I/We claim:

1. A shift register unit, comprising:
an inputting circuit, connected with an inputting terminal, a first signal terminal and a pulling up node, and configured to apply a signal at the first signal terminal to the pulling up node, under the control of a potential at the inputting terminal;
a resetting circuit, connected with a resetting terminal, a second signal terminal and the pulling up node, and configured to apply a signal at the second signal terminal to the pulling up node, under the control of a potential at the resetting terminal;
an outputting circuit, connected with an outputting terminal, a first clock terminal and the pulling up node, and configured to apply a signal at the first clock terminal to the outputting terminal according to a potential at the pulling up node;
a pulling down circuit, connected with a third signal terminal, a second clock terminal, a constant level terminal, the outputting terminal, the pulling up node and a pulling down node, and configured to apply a signal at the constant level terminal to the pulling up node and the outputting terminal according to the potential at the pulling down node, and to apply a signal at the constant level terminal to the pulling up node and the outputting terminal under the control of a potential at the third signal terminal;
a pull-down controlling circuit, connected with the second clock terminal, the pulling up node, the pulling down node and the constant level terminal, and configured to control the potential at the pulling down node according to the signal at the second clock terminal and the potential of the pulling up node; and
a storage capacitor, having a first terminal connected with the pulling up node and a second terminal connected with the pulling down node.

2. The shift register unit of claim 1, wherein the inputting circuit comprises a first transistor having a gate connected with the inputting terminal, a first terminal connected with the first signal terminal and a second terminal being connected with the pulling up node.

3. The shift register unit of claim 2, wherein the resetting circuit comprises a second transistor having a gate connected with the resetting terminal, a first terminal connected with the pulling up node and a second terminal connected with the second signal terminal.

4. The shift register unit of claim 3, wherein the outputting circuit comprises a third transistor having a gate connected with the pulling up node, a first terminal connected with the first clock terminal and a second terminal connected with the outputting terminal.

5. The shift register unit of claim 4, wherein the pulling down circuit comprises a fourth transistor, a fifth transistor, a sixth transistor, a seventh transistor, an eighth transistor and a ninth transistor, wherein:
the fourth transistor has a gate connected with the second clock terminal, a first terminal connected with the outputting terminal and a second terminal connected with the constant level terminal;
the fifth transistor has a gate connected with the pulling down node, a first terminal connected with the pulling up node and a second terminal connected with the constant level terminal;
the sixth transistor has a gate connected with the pulling down node, a first terminal connected with the outputting terminal and a second terminal connected with the constant level terminal;
the seventh transistor has a gate connected with the third signal terminal, a first terminal connected with the pulling up node and a second terminal connected with the constant level terminal;
the eighth transistor has a gate connected with the third signal terminal, a first terminal connected with the pulling down node and a second terminal connected with the third signal terminal; and
the ninth transistor has a gate connected with the third signal terminal, a first terminal connected with the outputting terminal and a second terminal connected with the constant level terminal.

6. The shift register unit of claim 5, wherein the pull-down controlling circuit comprises a tenth transistor, an eleventh transistor, a twelfth transistor and a thirteenth transistor, wherein:
the tenth transistor has a gate connected with a second terminal of the thirteenth transistor, a first terminal connected with the second clock terminal and a second terminal connected with the pulling down node;
the eleventh transistor has a gate connected with the pulling up node, a first terminal connected with the pulling down node and a second terminal connected with the constant level terminal;
the twelfth transistor has a gate connected with a pulling up node, a first terminal connected with the second terminal of the thirteenth transistor and a second terminal connected with the constant level terminal; and
the thirteenth transistor has a gate connected with the second clock terminal and a first terminal connected with the second clock terminal.

7. The shift register unit of claim 6, wherein all of the transistors are N-type transistors.

8. The shift register unit of claim 6, wherein all of the transistors are P-type transistors.

9. A gate driving circuit, comprising:
a plurality of cascaded shift register units, each of which is the shift register unit of claim 1.

10. A method for driving the shift register unit of claim 1, comprising:
providing a turning off signal to the constant level terminal and a turning on signal to the third signal terminal at a Blank time, so as to apply the turning off signal at the constant level terminal to the pulling up node and the outputting terminal.

11. The method of claim 10, wherein the shift register unit comprises N-type transistors, and a high potential is provided to the first signal terminal, a low potential is provided to the second signal terminal, and a low potential is provided to the constant level terminal, the method further comprising:
inputting a high potential to the inputting terminal, a low potential to the first clock terminal, a high potential to the second clock terminal, a low potential to the resetting terminal, and a low potential to the third signal terminal, at a Charging time;
inputting a low potential to the inputting terminal, a high potential to the first clock terminal, a low potential to the second clock terminal, a low potential to the resetting terminal, and a low potential to the third signal terminal, at an Outputting time;
inputting a low potential to the inputting terminal, a low potential to the first clock terminal, a high potential to the second clock terminal, a high potential to the resetting terminal, and a low potential to the third signal terminal, at a Resetting time;
inputting a low potential to the inputting terminal, a high potential to the first clock terminal and the second clock terminal alternatively, a low potential to the resetting terminal, a low potential to the third signal terminal, at a Holding time; and
inputting a low potential to the inputting terminal, a low potential to the first clock terminal, a low potential to the second clock terminal, a low potential to the resetting terminal, and a high potential to the third signal terminal, at the Blank time.

12. The method of claim 10, wherein the shift register unit comprises N-type transistors, and a low potential is provided to the first signal terminal, a high potential is provided to the second signal terminal, and a low potential is provided to the constant level terminal, the method further comprising:
inputting a high potential to the resetting terminal, a low potential to the first clock terminal, a high potential to the second clock terminal, a low potential to the inputting terminal, and a low potential to the third signal terminal, at a Charging time;
inputting a low potential to the resetting terminal, a high potential to the first clock terminal, a low potential to the second clock terminal, a low potential to the inputting terminal, and a low potential to the third signal terminal, at an Outputting time;
inputting a low potential to the resetting terminal, a low potential to the first clock terminal, a high potential to the second clock terminal, a high potential to the inputting terminal, and a low potential to the third signal terminal, at a Resetting time;
inputting a low potential to the resetting terminal, a high potential to the first clock terminal and the second clock terminal alternatively, a low potential to the inputting terminal, a low potential to the third signal terminal, at a Holding time; and
inputting a low potential to the resetting terminal, a low potential to the first clock terminal, a low potential to the second clock terminal, a low potential to the inputting terminal, and a high potential to the third signal terminal, at the Blank time.

13. The method of claim 10, wherein the shift register unit comprises P-type transistors, and a low potential is provided to the first signal terminal, a high potential is provided to the second signal terminal, and a high potential is provided to the constant level terminal, the method further comprising:
inputting a low potential to the inputting terminal, a high potential to the first clock terminal, a low potential to the second clock terminal, a high potential to the resetting terminal, and a high potential to the third signal terminal, at a Charging time;
inputting a high potential to the inputting terminal, a low potential to the first clock terminal, a high potential to the second clock terminal, a high potential to the resetting terminal, and a high potential to the third signal terminal, at an Outputting time;
inputting a high potential to the inputting terminal, a high potential to the first clock terminal, a low potential to the second clock terminal, a low potential to the resetting terminal, and a high potential to the third signal terminal, at a Resetting time;
inputting a high potential to the inputting terminal, a low potential to the first clock terminal and the second clock terminal alternatively, a high potential to the resetting terminal, and a high potential to the third signal terminal, at a Holding time; and
inputting a high potential to the inputting terminal, a high potential to the first clock terminal, a high potential to the second clock terminal, a high potential to the resetting terminal, and a low potential to the third signal terminal, at the Blank time.

14. The method of claim 10, wherein the shift register unit comprises P-type transistors, and a high potential is provided to the first signal terminal, a low potential is provided to the second signal terminal, and a high potential is provided to the constant level terminal, the method further comprising:
inputting a low potential to the resetting terminal, a high potential to the first clock terminal, a low potential to the second clock terminal, a high potential to the inputting terminal, and a high potential to the third signal terminal, at a Charging time;
inputting a high potential to the resetting terminal, a low potential to the first clock terminal, a high potential to the second clock terminal, a high potential to the inputting terminal, and a high potential to the third signal terminal, at an Outputting time;
inputting a high potential to the resetting terminal, a high potential to the first clock terminal, a low potential to the second clock terminal, a low potential to the inputting terminal, and a high potential to the third signal terminal, at a Resetting time;
inputting a high potential to the resetting terminal, a low potential to the first clock terminal and the second clock terminal alternatively, a high potential to the inputting terminal, and a high potential to the third signal terminal, at a Holding time; and
inputting a high potential to the resetting terminal, a high potential to the first clock terminal, a high potential to the second clock terminal, a high potential to the inputting terminal, and a low potential to the third signal terminal, at the Blank time.

15. A method of driving the shift register unit of claim 2, comprising:
providing a turning off signal to the constant level terminal and a turning on signal to the third signal terminal, at a Blank time, so as to apply the turning off signal at the constant level terminal to the pulling up node and the outputting terminal.

16. A method of driving the shift register unit of claim 3, comprising:
providing a turning off signal to the constant level terminal and a turning on signal to the third signal terminal, at a Blank time, so as to apply the turning off signal at the constant level terminal to the pulling up node and the outputting terminal.

17. A method of driving the shift register unit of claim 4, comprising:
providing a turning off signal to the constant level terminal and a turning on signal to the third signal terminal, at a Blank time, so as to apply the turning off signal at the constant level terminal to the pulling up node and the outputting terminal.

18. A method of driving the shift register unit of claim 5, comprising:
providing a turning off signal to the constant level terminal and a turning on signal to the third signal terminal, at a Blank time, so as to apply the turning off signal at the constant level terminal to the pulling up node and the outputting terminal.

19. A method of driving the shift register unit of claim 6, comprising:
providing a turning off signal to the constant level terminal and a turning on signal to the third signal terminal, at a Blank time, so as to apply the turning off signal at the constant level terminal to the pulling up node and the outputting terminal.
